(19) United States
(12) Patent Application Publication
(10) Pub. No.: US 2018/0219163 A1
(43) Pub. Date: Aug. 2, 2018

(54) Flexible Array Substrate, the Preparation Method Thereof, and Flexible Display Device

(71) Applicant: WUHAN CHINA STAR OPTOLECTRONICS TECHNOLOGY CO., LTD, Hubei (CN)

(72) Inventor: Fang QIN, Shenzhen, Guangdong (CN)

(73) Assignee: Wuhan China Star Optoelectronics Technology Co., Ltd., Wuhan, Hubei (CN)

(21) Appl. No.: 15/129,800

(22) PCT Filed: Aug. 3, 2016
(86) PCT No.: PCT/CN2016/093004

§ 371 Date: Sep. 27, 2016

(30) Foreign Application Priority Data
Jul. 20, 2016 (CN) 201610572816.0

(51) Int. Cl. H01L 51/00; H01L 51/05; H01L 51/50; H01L 51/52; H01L 51/56

(52) U.S. Cl. CPC H01L 51/0097; H01L 51/0516; H01L 51/5056; H01L 51/56; H01L 51/5206; H01L 51/5221; H01L 51/5072

(57) ABSTRACT

The present disclosure discloses a flexible array substrate, comprising a flexible substrate and a buffer layer on the flexible substrate. Multiple thin film transistors are provided on the buffer layer in array. An interlayer dielectric layer is provided on the thin film transistor. The interlayer dielectric layer covers the buffer layer. Wherein, an interconnecting structure is provided between the interlayer dielectric layer and the buffer layer. At least one interconnecting structure is respectively provided at both sides of each column of the thin film transistor. The interconnecting structure extends toward the direction parallel to the bending axis of the flexible array substrate. The present disclosure further discloses a preparation method of flexible array substrate and a flexible display device with the flexible array substrate. The present disclosure provides the interconnecting structure, which enhances the connecting performance of the interconnecting layer in the flexible array substrate.

### BACKGROUND OF THE INVENTION

### 1. Field of the Invention

The present disclosure relates to the fields of display technology, and in particular to a flexible array substrate and the preparation method thereof, and further to a flexible display device with above flexible array substrate.

### 2. The Related Arts

In recent years, flat panel display technology has been rapid developed, no matter the size of the screen or the display quality have made great progress. With its bending properties, the flexible display device can be competent in many areas requiring surface display, such as various fields of smart cards, electronic paper, smart labels, as well as the conventional flat panel display device which can be applied to. The flexible display device will occupy a huge market in the future display market with its dreamy and beautiful appearance. Typically, the flexible display device includes stacked flexible array substrates and electroluminescent devices. A transparent flexible cover is provided on the electroluminescent device.

FIG. 1 shows the flexible array substrate according to the existing technology, which comprises a flexible substrate 1, a buffer layer 2 on the flexible substrate 1, and multiple thin film transistors 3 provided on the buffer layer 2 in array (FIG. 1 only shows one of the thin film transistors 3). Wherein, the thin film transistor 3 comprises an active layer 4, a gate 5, a source 6, and a drain 7. A gate insulating layer 8 is provided between the active layer 4 and the gate 5. An interlayer dielectric (ILD) 9 is provided on the gate 5, and the interlayer dielectric 9 covers the buffer layer 2 and interconnects each layer as one. The interlayer dielectric 9 is also used to isolate the source 6, drain 7, and the gate 5. The source 6 and the drain 7 are respectively connected to the active layer 4 through a via provided on the interlayer dielectric layer 9.

In the above flexible array substrate, the buffer layer 2, the gate insulating layer 8, and the interlayer dielectric layer 9 are typically made of inorganic oxide, such as SiOₓ, SiNₓ, etc. The bending of the flexible array substrate has less damage for the organic and metallic materials therein, but has more serious damage for inorganic oxide with poor flexibility. Especially when bent into small radius of curvature, it could easily lead to the flexible array substrate with the above inorganic oxide having the problems of cracking, peeling, and dislocation. In regard to the gate insulating layer 8, it can pattern the gate insulating layer 8, which reduces the coverage area thereof to reduce the stress, decreasing the problems of cracking, peeling, and dislocation. However, the interconnected area between the interlayer dielectric layer 9 and the buffer layer 2 is larger, both interconnecting performance is poor. When bending flexible array substrate, the interlayer dielectric layer 9 is easily drop off the buffer layer 2 or broken, which affects the quality of the flexible array substrate

### SUMMARY OF THE INVENTION

In view of this, the present disclosure provides a flexible array substrate and the preparation method thereof, which enhances the connecting performance of the interconnecting layer in the flexible array substrate, improving the problems of missing or breakage occurred in the interconnecting layer, increasing the quality of the flexible array substrate.

To achieve the above object of the disclosure, the technical solution adopted by the present disclosure is to provide a flexible array substrate, comprising a flexible substrate and a buffer layer on the flexible substrate, multiple thin film transistors being provided on the buffer layer in array, an interlayer dielectric layer being provided on the thin film transistor, the interlayer dielectric layer covering the buffer layer; wherein, an interconnecting structure is provided between the interlayer dielectric layer and the buffer layer, at least one interconnecting structure is respectively provided at both sides of each column of the thin film transistor, the interconnecting structure extends toward the direction parallel to the bending axis of the flexible array substrate.

Wherein, one part of the interconnecting structure is embedded in the interlayer dielectric layer, the other part thereof is embedded in the buffer layer.

Wherein, the section of the part of the interconnecting structure embedded in the buffer layer is square; the section of the part thereof embedded in the interlayer dielectric layer is semicircular or R-chamfered trapezoid.

Wherein, the interconnecting structure comprises multiple first structure portions and multiple second structure portions alternately spaced along the longitudinal direction; the first structure portion is a stripe structure with length thereof several times greater than the width thereof, the second structure portion is a dot structure with length thereof equal to or nearly equal to width thereof.

Wherein, the interconnecting structure is made of organic photoresist material.

Wherein, the thin film transistor comprises an active layer, a gate, a source, and a drain; the active layer is formed on the buffer layer, the gate is formed at the active layer, a gate insulating layer is provided between the active layer and the gate; the interlayer dielectric layer is provided on the gate, the source and the drain are respectively provided on the interlayer dielectric layer, the source and the drain are respectively connected to the active layer through a via provided on the interlayer dielectric layer.

Wherein, the active layer is made of indium gallium zinc oxide.

Wherein, the gate insulating layer covers the intermediate region of the active layer, the active layer is exposed at both sides of the gate insulating layer; transform the exposed active layer into a conductor using ion implantation process or plasma bombardment process, forming a source connecting portion at one end of the active layer, and forming a drain connecting portion at the other end thereof; the source is connected to the source connecting portion, the drain is connected to the drain connecting portion.

The preparation method of flexible array substrate as mentioned above, comprising: S1, providing a flexible substrate, forming a buffer layer on the flexible substrate; S2, preparing an active layer and a gate, which forms a thin film transistor, on the buffer layer; S3, forming a patterned embedding region of an interconnecting structure through a mask process at both sides of the active layer on the buffer layer; S4, forming the interconnecting structure on the embedding region through the mask process; S5, preparing an interlayer dielectric layer on the gate, and covering the buffer layer on the interlayer dielectric layer, one part of the interconnecting structure being embedded in the interlayer dielectric layer; S6, etching a via communicating to the active layer in the interlayer dielectric layer; S7, preparing a source and a drain of the thin film transistor on the interlayer dielectric layer through the mask process, the source and the drain being respectively connected to the active layer through the via.

The present disclosure further provides a flexible display device, which comprises stacked flexible array substrates and an electroluminescent device. A transparent flexible cover is further provided on the electroluminescent device. Wherein, the flexible display device utilizes the flexible array substrate as mentioned above.

The present disclosure provides a flexible array substrate and a corresponding flexible display device, which provides an interconnecting structure between the interlayer dielectric layer and the buffer layer. The interconnecting structure is made of the material with good flow and flexibility, which can effectively release the stress of the interlayer dielectric layer to avoid the stress concentration, enhance the connecting performance of the interconnecting layer (interlayer dielectric layer and buffer layer) in the flexible array substrate, improve the problems of missing or breakage occurred in the interconnecting layer, increase the quality of the flexible array substrate, and enhance the overall flexibility of the flexible display device.

### BRIEF DESCRIPTION OF THE DRAWINGS

FIG. 1 is a schematic view illustrating the structure of the flexible array substrate according to the existing technology;

FIG. 2 is a schematic view illustrating the structure of the flexible array substrate according to the embodiment of the present disclosure;

FIG. 3 is a distribution diagram of the interconnecting structure on the buffer layer according to the embodiment of the present disclosure;

FIG. 4 is a sectional structure of the interconnecting structure according to the preferred embodiment of the present disclosure;

FIG. 5 is flow diagram of the preparation method of flexible array substrate according to the embodiment of the present disclosure; and

FIG. 6 is schematic view illustrating the structure of the flexible display device according to the embodiment of the present disclosure

### DETAILED DESCRIPTION OF THE PREFERRED EMBODIMENTS

To make the purposes, the technical solutions, and the advantages of this invention more apparent, the detailed descriptions accompanying drawings and the embodiment of the present invention are as follows. Examples of these preferred embodiments in the drawings have been illustrated. The embodiments of the present invention as shown in the drawings and according to the drawings are merely exemplary, and the present invention is not limited to these embodiments

Here, it should be noted that in order to avoid unnecessary details obscure the present invention, the drawings only show the structures and/or the processing steps closely related to the solution according to the present invention, which omits other details less related to the present invention.

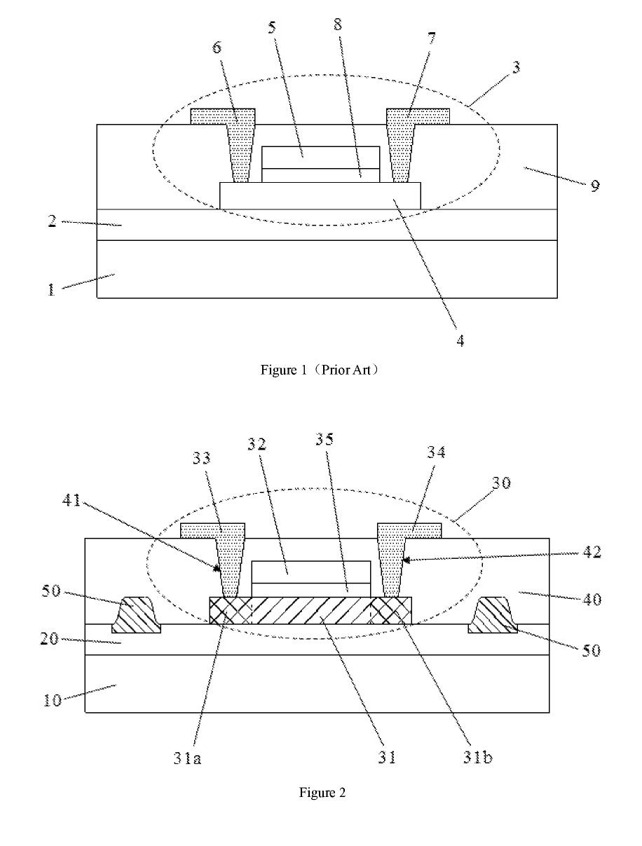

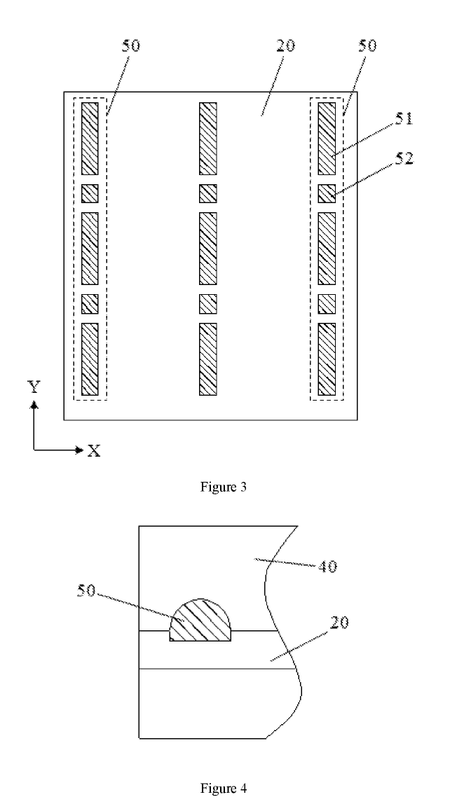

First, the present embodiment provides a flexible array substrate, as shown in FIG. 2. The flexible array substrate comprises a flexible substrate 10 and a buffer layer 20 on the flexible substrate 10. Multiple thin film transistors 30 (only one thin film transistor 30 is shown in FIG. 2) are provided on the buffer layer 20 in array. An interlayer dielectric layer 40 is provided on the thin film transistor 30. The interlayer dielectric layer 40 covers the buffer layer 20. Wherein, an interconnecting structure 50 is provided between the interlayer dielectric layer 40 and the buffer layer 20. At least one interconnecting structure 50 is respectively provided at both sides of each column of the thin film transistor 30. The interconnecting structure 50 extends toward the direction parallel to the bending axis of the flexible array substrate. FIG. 3 shows a distribution diagram of the interconnecting structure 50 on the buffer layer 20. As shown in FIG. 3, it can be understood that each interconnecting structure 50 extends along the direction (Y direction as shown in FIG. 3) of the bending axis of the flexible array substrate on the buffer layer 20, multiples interconnecting structures 50 arranged in parallel in the direction (X direction as shown in FIG. 3) perpendicular to the bending axis thereof. There is one row of thin film transistors (not shown in FIG. 3) arranged between every two interconnecting structures 50.

Wherein, the interconnecting structure 50 is made of the material with good flow and flexibility, which can enhance the connecting performance of the interlayer dielectric layer 40 and the buffer layer 20 in the flexible array substrate, effectively release the stress of the interlayer dielectric layer 40 to avoid the stress concentration. When bending the flexible array substrate, the stress of the interlayer dielectric layer 40 with poor flexibility can be released through the interconnecting structure 50, which improves the problems of missing or breakage occurred in the interconnecting layer 40. Specifically, the interconnecting structure 50 is made of organic photoresist material.

Wherein, in order to further improve the connecting performance of the interlayer dielectric layer 40 and the buffer layer 20, as shown in FIG. 2, one part of the interconnecting structure 50 is embedded in the interlayer dielectric layer 40, the other part thereof is embedded in the buffer layer 20. Specifically, in the present embodiment, the section of the part of the interconnecting structure 50 embedded in the buffer layer 20 is square, and the section of the part thereof embedded in the interlayer dielectric layer 40 is semicircular or R-chamfered trapezoid, so that the contact interface between the interconnecting structure 50 and the interlayer dielectric layer 40 is smooth, then the interconnecting structure 50 can effectively release the stress of the interlayer dielectric layer 40.

In another preferred embodiment, as shown in FIG. 4, the section of the part of the interconnecting structure 50 embedded in the interlayer dielectric layer 40 can also be designed as semicircular, or other shape having smooth surface.

Wherein, as shown in FIG. 3, in the present embodiment, the interconnecting structure 50 comprises multiple first structure portions 51 and multiple second structure portions 52 (FIG. 3 only shows several first structure portions 51 and second structure portions 52) alternately spaced along the longitudinal direction. The first structure portion 51 is a stripe structure with length thereof several times greater than the width thereof, the second structure portion 52 is a dot structure with length thereof equal to or nearly equal to width thereof. In a preferred embodiment, the projection portion (the portion embedding in the interlayer dielectric layer 40) of the second structure portions 52 in the buffer layer 20 is a hemispherical structure. Here, alternately spacing refers to the first structural portion 51 and the second structure portion 52 not even as one, but having an interval between the two. By using the interconnecting structure 50 with the stripe structure and the dot structure alternately spaced, it can better release the stress of the interlayer dielectric layer 40 to avoid the stress concentration.

Wherein, referring to FIG. 2, the thin film transistor 30 comprises an active layer 31, a gate 32, a source 33, and a drain 34. In the present embodiment, the thin film transistor 30 is a thin film transistor with top gate structure. Specifically, as shown in FIG. 2, the active layer 31 is formed on the buffer layer 20, the gate 32 is formed at the active layer 31, and a gate insulating layer 31 is provided between the active layer 31 and the gate 32. The interlayer dielectric layer 40 is provided on the gate 32, the source 33 and the drain 34 are respectively provided on the interlayer dielectric layer 40, the source 33 and the drain 34 are respectively connected to the active layer 31 through vias 41, 42 provided on the interlayer dielectric layer 40.

Wherein, in the present embodiment, the active layer 31 is made of indium gallium zinc oxide (IGZO).

Furthermore, in the present embodiment, as shown in FIG. 2, the gate insulating layer 35 covers the intermediate region of the active layer 31, the active layer 35 is exposed at both sides of the gate insulating layer 31. Transform the exposed active layer 31 into a conductor using ion implantation process or plasma bombardment process, which forms a source connecting portion 31a at one end of the active layer 31, and forms a drain connecting portion 31b at the other end thereof. The source 33 is connected to the source connecting portion 31a, and the drain 34 is connected to the drain connecting portion 31b. As the above structure, the source connecting portion 31a, the drain connecting portion 31b, and the active layer 31 are same layer and an integral structure, and the source connecting portion 31a and the drain connecting portion 31b have good conductivity. Therefore, the source 33 and the drain 34 are respectively connected to the active layer 31 through the source connecting portion 31a and the drain connecting portion 31b, which reduces the contact resistance between the source 33 and the drain 34, and the active layer 31, further improving the device performance.

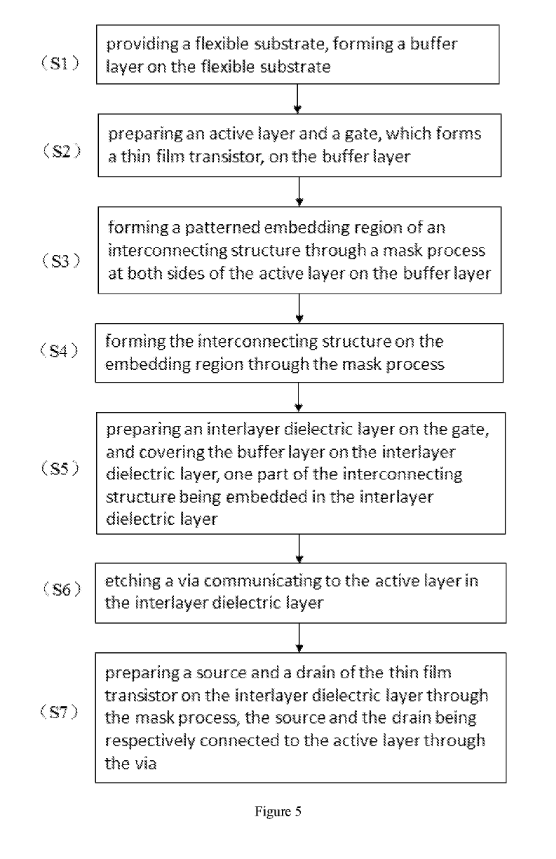

The following refers to FIG. 5 combing with FIGS. 2 and 3, the preparation method of the flexible array substrate as mentioned above is described in detail. As shown in FIG. 3, the method comprises:

S1, providing a flexible substrate 10, forming a buffer layer 20 on the flexible substrate 10. Wherein, the buffer layer 20 can be prepared by deposition process, such as magnetron sputtering process, plasma enhanced chemical vapor deposition process (PECVD), atomic layer deposition (ALD) process, or solution method. The flexible substrate 10 is made of polyimide (PI) or polyethylene terephthalate (PET).

S2, preparing an active layer 31 and a gate 32, which forms a thin film transistor 30, on the buffer layer 20. Specifically, the step comprises:

S21, depositing a semiconductor thin film used to form the active layer 31 on the buffer layer 20 using magnetron sputtering process, plasma enhanced chemical vapor deposition process (PECVD), atomic layer deposition (ALD) process, or solution method. In the present embodiment, it is IGZO semiconductor thin film.

S22, etching the IGZO semiconductor thin film to form the patterned active layer 31 through a photo-mask process.

S23, sequentially preparing a gate insulating thin film layer and a gate thin film layer on the buffer layer 20 with the active layer 31, the gate insulating thin film layer be made of SiOₓ or SiNₓ, the gate thin film layer mainly be made of metallic conductive material. Wherein, the gate insulating thin film layer and the gate thin film layer can be prepared by deposition process, such as magnetron sputtering process, plasma enhanced chemical vapor deposition process (PECVD), atomic layer deposition (ALD) process, or solution method.

S24, etching the gate insulating thin film layer and the gate thin film layer to form a gate insulating layer 35 and the gate 32 through a photo-mask process.

S3, forming a patterned embedding region of an interconnecting structure through a mask process at both sides of the active layer 31 on the buffer layer 20.

S4, forming the interconnecting structure 50 on the embedding region through the mask process. Specifically, deposit a thin film used to form the interconnecting structure 50 on the buffer layer 20 corresponding to the embedding region. In the present embodiment, it uses organic photoresist material, which can be prepared using magnetron sputtering process, plasma enhanced chemical vapor deposition process (PECVD), atomic layer deposition (ALD) process, or solution method. And then etch the thin film layer to form the interconnecting structure 50 through a photo-mask process.

S5, preparing an interlayer dielectric layer 40 on the gate 32, and covering the buffer layer 20 on the interlayer dielectric layer 40, one part of the interconnecting structure 50 being embedded in the interlayer dielectric layer 40. Wherein, the interlayer dielectric layer 40 is made of SiOₓ or SiNₓ, which can be prepared using magnetron sputtering process, plasma enhanced chemical vapor deposition process (PECVD), atomic layer deposition (ALD) process, or solution method.

S6, etching vias 41, 42 communicating to the active layer 31 in the interlayer dielectric layer 40.

S7, preparing a source 33 and a drain 34 of the thin film transistor 30 on the interlayer dielectric layer 40 through the mask process, the source 33 and the drain 34 being respectively connected to the active layer 31 through the vias 41, 42. Specifically, prepare an electroconductive metal thin film layer used to form the source 33 and the drain 34 on the interlayer dielectric layer 40. The electroconductive metal thin film layer can be prepared using magnetron sputtering process, plasma enhanced chemical vapor deposition process (PECVD), atomic layer deposition (ALD) process, or solution method. And then etch the electroconductive metal thin film layer to form the patterned source 33 and the drain 34 through a photo-mask process.

In the above preparation process, each photo-mask process comprises mask, exposing, developing, etching and stripping processes, etc. Wherein, etching process comprises dry etching and wet etching. In each step, the parameters of the photo-mask process may be different. But in the manufacturing field of display, the photo-mask process has been more mature existing technology, which is not described in detail.

It should be noted that the flexible substrate used in the flexible array substrate has poor support capacity. Therefore, it usually provides a rigid substrate firstly, places the flexible substrate on the rigid substrate, and then prepares each layer. After finishing the preparation of the flexible array substrate or even the entire display device, it removes the rigid substrate.

Furthermore, in the present embodiment, the above step S24 specifically comprises:

Firstly, forming the gate insulating layer 35 and the gate 32 using a top gate self-aligned process, the gate insulating layer 35 only covering the intermediate region of the active layer 31, the active layer 31 being exposed at both sides of the gate insulating layer 35.

Then, transforming the exposed active layer 31 into a conductor using ion implantation process or plasma bombardment process, forming a source connecting portion 31a at one end of the active layer, and forming a drain connecting portion 31b at the other end thereof; the source connecting portion being 31a used to connected to the source 33, the drain connecting portion being 31b used to connected to the drain 34.

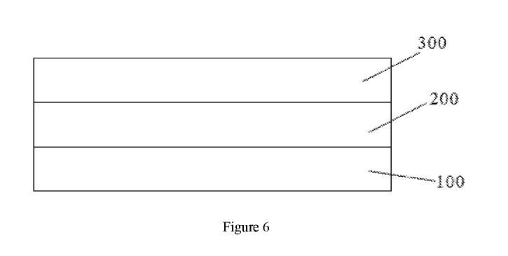

Furthermore, the present embodiment further provides a flexible display device, as shown in FIG. 6. The flexible display device comprises stacked flexible array substrates 100 and an electroluminescent device 200. A transparent flexible cover 300 being further provided on the electroluminescent device 200. Wherein, the flexible array substrate 100 comprises the flexible array substrate according to the above embodiment. Wherein, the electroluminescent device 200 usually comprises an anode, an organic functional layer formed on the anode, and a cathode formed on the organic functional layer. The anode and the cathode excite the organic functional layer to implement display. Wherein, the organic functional layer typically consists of three functional layers, which are respectively hole transport layer (HTL), emissive layer (EML), and electron transport layer (ETL). Each functional layer may be one layer or more than one layer. For example, the hole transport layer sometimes can be subdivided into hole injection layer and hole transport layer; the electron transport layer can be subdivided into electron transport layer and an electron injection layer, but the functions thereof are similar, so they are collectively referred to as hole transport function layer and electron transport functional layer.

In summary, the present disclosure provides a flexible array substrate and a corresponding flexible display device, which provides an interconnecting structure between the interlayer dielectric layer and the buffer layer. The interconnecting structure is made of the material with good flow and flexibility, which can effectively release the stress of the interlayer dielectric layer to avoid the stress concentration, enhance the connecting performance of the interconnecting layer (interlayer dielectric layer and buffer layer) in the flexible array substrate, improve the problems of missing or breakage occurred in the interconnecting layer, increase the quality of the flexible array substrate, and enhance the overall flexibility of the flexible display device.

It needs to notice that, in this article, the relational terms such as first and second is only used to distinguish one entity or operating another entity or an operation, it is not necessary to require or imply that there exists any such relationship or sequence between the entity and operation. Besides, the terms “comprise,” “include,” or any other variation are intended to cover a non-exclusive inclusion, thereby making that comprising a series of process, method, materials or apparatus of element not only comprise those elements, but also comprise other elements not expressly listed, or also comprise such inherent elements of process, method, materials or apparatus. In the absence of more restrictive conditions, limiting the elements by the statement “comprises a”, it doesn't exclude that it also exists other identical elements in comprising the process, method, materials or apparatus of element.

The above embodiments have been shown and described, but those skilled in the art should appreciate the inventive concept of the present disclosure is not limited to these embodiments. The above embodiments can be modified and changed variously without departing from the spirit and principles of the present disclosure.

What is claimed is:

1. A flexible array substrate, comprising a flexible substrate and a buffer layer on the flexible substrate, multiple thin film transistors being provided on the buffer layer in array, an interlayer dielectric layer being provided on the thin film transistor, the interlayer dielectric layer covering the buffer layer;
wherein, an interconnecting structure is provided between the interlayer dielectric layer and the buffer layer, at least one interconnecting structure is respectively provided at both sides of each column of the thin film transistor, the interconnecting structure extends toward the direction parallel to the bending axis of the flexible array substrate.

2. The flexible array substrate as claimed in claim 1, wherein one part of the interconnecting structure is embedded in the interlayer dielectric layer, the other part thereof is embedded in the buffer layer.

3. The flexible array substrate as claimed in claim 2, wherein the section of the part of the interconnecting structure embedded in the buffer layer is square; the section of the part thereof embedded in the interlayer dielectric layer is semicircular or R-chamfered trapezoid.

4. The flexible array substrate as claimed in claim 2, wherein the interconnecting structure comprises multiple first structure portions and multiple second structure portions alternately spaced along the longitudinal direction; the first structure portion is a stripe structure with length thereof several times greater than the width thereof, the second structure portion is a dot structure with length thereof equal to or nearly equal to width thereof.

5. The flexible array substrate as claimed in claim 4, wherein the interconnecting structure is made of organic photoresist material.

6. The flexible array substrate as claimed in claim 1, wherein the thin film transistor comprises an active layer, a gate, a source, and a drain; the active layer is formed on the buffer layer, the gate is formed at the active layer, a gate insulating layer is provided between the active layer and the gate; the interlayer dielectric layer is provided on the gate, the source and the drain are respectively provided on the interlayer dielectric layer, the source and the drain are respectively connected to the active layer through a via provided on the interlayer dielectric layer.

7. The flexible array substrate as claimed in claim 6, wherein the active layer is made of indium gallium zinc oxide.

8. The flexible array substrate as claimed in claim 7, wherein the gate insulating layer covers the intermediate region of the active layer, the active layer is exposed at both sides of the gate insulating layer; transform the exposed active layer into a conductor using ion implantation process or plasma bombardment process, forming a source connecting portion at one end of the active layer, and forming a drain connecting portion at the other end thereof; the source is connected to the source connecting portion, the drain is connected to the drain connecting portion.

9. A preparation method of flexible array substrate, comprising:
S1, providing a flexible substrate, forming a buffer layer on the flexible substrate;
S2, preparing an active layer and a gate, which forms a thin film transistor, on the buffer layer;
S3, forming a patterned embedding region of an interconnecting structure through a mask process at both sides of the active layer on the buffer layer;
S4, forming the interconnecting structure on the embedding region through the mask process;
S5, preparing an interlayer dielectric layer on the gate, and covering the buffer layer on the interlayer dielectric layer, one part of the interconnecting structure being embedded in the interlayer dielectric layer;
S6, etching a via communicating to the active layer in the interlayer dielectric layer;
S7, preparing a source and a drain of the thin film transistor on the interlayer dielectric layer through the mask process, the source and the drain being respectively connected to the active layer through the via.

10. The preparation method of flexible array substrate as claimed in claim 9, wherein the section of the part of the interconnecting structure embedded in the buffer layer is square; the section of the part thereof embedded in the interlayer dielectric layer is semicircular or R-chamfered trapezoid.

11. The preparation method of flexible array substrate as claimed in claim 10, wherein the interconnecting structure comprises multiple first structure portions and multiple second structure portions alternately spaced along the longitudinal direction; the first structure portion is a stripe structure with length thereof several times greater than the width thereof, the second structure portion is a dot structure with length thereof equal to or nearly equal to width thereof.

12. The preparation method of flexible array substrate as claimed in claim 11, wherein the interconnecting structure is made of organic photoresist material.

13. The preparation method of flexible array substrate as claimed in claim 9, wherein the active layer is made of indium gallium zinc oxide, a gate insulating layer is further provided between the active layer and the gate; the step S2 specifically comprises:
forming the gate insulating layer and the gate using a top gate self-aligned process, the gate insulating layer only covering the intermediate region of the active layer, the active layer being exposed at both sides of the gate insulating layer;
transforming the exposed active layer into a conductor using ion implantation process or plasma bombardment process, forming a source connecting portion at one end of the active layer, and forming a drain connecting portion at the other end thereof; the source connecting portion being used to connected to the source, the drain connecting portion being used to connected to the drain.

14. A flexible display device, comprising stacked flexible array substrates and an electroluminescent device, a transparent flexible cover being further provided on the electroluminescent device;
wherein, the flexible array substrate comprises a flexible substrate and a buffer layer on the flexible substrate, multiple thin film transistors are provided on the buffer layer in array, an interlayer dielectric layer is provided on the thin film transistor, the interlayer dielectric layer covers the buffer layer;
wherein, an interconnecting structure is provided between the interlayer dielectric layer and the buffer layer, at least one interconnecting structure is respectively provided at both sides of each column of the thin film transistor, the interconnecting structure extends toward the direction parallel to the bending axis of the flexible array substrate.

15. The flexible display device as claimed in claim 14, wherein one part of the interconnecting structure is embedded in the interlayer dielectric layer, the other part thereof is embedded in the buffer layer.

16. The flexible display device as claimed in claim 15, wherein the section of the part of the interconnecting structure embedded in the buffer layer is square; the section of the part thereof embedded in the interlayer dielectric layer is semicircular or R-chamfered trapezoid.

17. The flexible display device as claimed in claim 15, wherein the interconnecting structure comprises multiple first structure portions and multiple second structure portions alternately spaced along the longitudinal direction; the first structure portion is a stripe structure with length thereof several times greater than the width thereof, the second structure portion is a dot structure with length thereof equal to or nearly equal to width thereof.

18. The flexible display device as claimed in claim 17, wherein the interconnecting structure is made of organic photoresist material.

19. The flexible display device as claimed in claim 14, wherein the thin film transistor comprises an active layer, a gate, a source, and a drain; the active layer is formed on the buffer layer, the gate is formed at the active layer, a gate insulating layer is provided between the active layer and the gate; the interlayer dielectric layer is provided on the gate, the source and the drain are respectively provided on the interlayer dielectric layer, the source and the drain are respectively connected to the active layer through a via provided on the interlayer dielectric layer.

20. The flexible display device as claimed in claim 19, wherein the active layer is made of indium gallium zinc oxide, the gate insulating layer covers the intermediate region of the active layer, the active layer is exposed at both sides of the gate insulating layer; transform the exposed active layer into a conductor using ion implantation process or plasma bombardment process, forming a source connecting portion at one end of the active layer, and forming a drain connecting portion at the other end thereof; the source is connected to the source connecting portion, the drain is connected to the drain connecting portion.
